(19) United States
(12) Patent Application Publication
(10) Pub. No.: US 2009/0039762 A1
(43) Pub. Date: Feb. 12, 2009

(54) WHITE LED DEVICE COMPRISING DUAL-MOLD AND MANUFACTURING METHOD FOR THE SAME

(76) Inventors: Jun-Kyu Park, Gunpo-city (KR); Jae-Hyoung Yoo, Jeonju-city (KR)

Correspondence Address: JHK LAW, P.O. BOX 1078, LA CANADA, CA, 91012-1078, US

(21) Appl. No.: 10/596,436

(22) PCT Filed: Dec. 30, 2004
(86) PCT No.: PCT/KR2004/003522

§ 371 Date: Jun. 13, 2006

(30) Foreign Application Priority Data
Jan. 2, 2004 (KR) 10-2004-0000094

(51) Int. Cl. H01L 33/00; H01J 1/62

(52) U.S. Cl. 313/502; 438/26; 257/E33.056

(57) ABSTRACT

A conventional high-luminance white light emitting diode (LED) device has the disadvantage of it being difficult to achieve high luminance and excellent and uniform quality since emitted light is weaker in the red wavelength region than at yellow wavelengths. The present invention provides a high-luminance white LED device with improved color rendering and spectrum distribution, and a method of manufacturing the same. The white LED device according to one embodiment of the present invention is characterized by dual molds. The white LED device includes: an LED chip mounting member for mounting an LED chip; at least one blue LED chip or ultraviolet LED chip mounted on the LED chip mounting member; a first mold having a transparent epoxy resin and a first phosphor and sealing the blue or ultraviolet LED chip, the first phosphor dispersed in the transparent epoxy resin to convert light emitted from the blue or ultraviolet LED chip into first light having a first wavelength; and a second mold having a transparent epoxy resin and a second phosphor and formed on the first mold, the second phosphor dispersed in the transparent epoxy resin to convert light emitted from the blue or ultraviolet LED chip into second light having a second wavelength, the second light being white light obtained by combination of the emitted light with the first light. The white LED device having the dual molds can be a lamp-type LED device, an injection-molded housing package-type LED device, or a transfer-molded chip-type LED device.

### TECHNICAL FIELD

The present invention relates to a white light emitting diode (LED) device and a method of manufacturing the same, and more particularly, to a white LED device using a blue or ultraviolet LED chip, and a method of manufacturing the same.

### BACKGROUND ART

An LED device is a kind of semiconductor device for converting electrical energy into light energy using a characteristic of compound semiconductors. LED devices come in blue, white, and seven-color varieties, and their applications are continuously increasing. Among the three varieties, white LED devices are currently used in high-luminance flashlights, in a backlight of a liquid crystal display (LCD) of portable electronic devices (portable phones, camcorders, digital cameras and personal digital assistants (PDAs)), in electronic display boards, in indicators and switches, and in display lights and traffic lights, etc.

The white LED device converts a part of light emitted from an LED chip into light having a longer wavelength, to thereby emit white light. The LED chip is a semiconductor device having a PN junction, which is formed using a compound such as GaAsP, GaAlAs, GaP, InGaAlP, or GaN. If a predetermined voltage is applied to the PN junction, electrons and holes come together and combine, emitting light. The emitted light is monochromatic, i.e., has a single wavelength. The blue LED chip emits a blue light with a wavelength of about 440 nm to 475 nm, and the ultraviolet LED chip emits an ultraviolet light with a wavelength of about 350 nm to 410 nm. The emitted ultraviolet light or blue light is converted into light having a different wavelength, by using phosphor. The phosphors are dispersed in a mold formed of epoxy resin for protecting the LED chip. A dispersed state of each of the phosphors has a great influence on luminance and spectrum distribution of the emitted white light.

FIGS. 1 through 3 are schematic sectional views of conventional white LED devices. Here, FIG. 1 illustrates a conventional lamp-type white LED device, FIG. 2 illustrates a conventional chip-type white LED device manufactured using a transfer-molding technique, and FIG. 3 illustrates a conventional chip-type white LED device manufactured using an injection-molded housing package.

Referring to FIGS. 1 through 3, the white LED device includes a blue LED chip 14; an LED chip mounting member such as a printed circuit board or a lead frame; an adhesive 16 for adhering the blue LED chip 14 to the LED chip mounting member; and a bonding wire 18 for electrically connecting an electrode 20 or a lead 22 of the LED chip mounting member with a bonding pad formed on the blue LED chip 14; and a mold 10 and 12. Additionally, the mold 10 and 12 includes a transparent epoxy resin 10 for sealing the LED chip 14 and the bonding wire 18; and phosphor 12 uniformly dispersed throughout the epoxy resin 10 for converting light emitted from the blue LED chip 14 into yellow light. An Yttrium-aluminum-garnet (Y₃Al₅O₁₂: Ce, YAG)-based compound is a yellow phosphor that is widely used as the phosphor 12.

FIG. 4 is a graph of relative intensity versus wavelength of light emitted from a conventional white LED device.

Referring to FIG. 4, the conventional white LED device has two peaks: a narrow peak in the blue wavelength region and a wider peak in the yellow wavelength region. It can be understood that the intensity is relatively weak in the red wavelength region. This is because the conventional white LED device has only phosphor for converting blue light into yellow light. As a result, the conventional white LED device has a drawback in that since the emitted white light is weaker in intensity in the red wavelength region than in the yellow wavelength region, it is not recognized as being very close to natural white light.

Further, the conventional white LED device has a disadvantage in that since a spectrum of the emitted white light varies widely according to the intensity of the yellow wavelength region, it is difficult to mass produce the white LED device with high luminance and spectral uniformity. Additionally, since the spectrum of white light output by the conventional white LED device has the single peak in the yellow wavelength region, a process for manufacturing the device is complicated.

Additionally, the phosphor should be uniformly dispersed in the transparent epoxy resin so as to provide good optical characteristics. To this end, it is necessary to prevent the phosphor, which has a large specific gravity (varying from about 3.8 to 6.0 depending on the phosphor) from sinking to the bottom of the much lighter transparent epoxy resin (specific gravity ranging from about 1.1 to 1.5).

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic sectional view of a conventional lamp-type white LED device;

FIG. 2 is a schematic sectional view of a conventional chip-type white LED device;

FIG. 3 is a schematic sectional view of a conventional lead frame-type white LED device;

FIG. 4 is a graph of relative intensity versus wavelength of light emitted from a conventional white LED device;

FIG. 5 is a schematic sectional view of a lamp-type white LED device having dual molds according to the present invention;

FIG. 6 is a schematic sectional view of a chip-type white LED device having dual molds according to the present invention;

FIG. 7 is a schematic sectional view of a lead frame-type white LED device having dual molds according to the present invention;

FIG. 8 is a graph of relative intensity versus wavelength of light emitted from a white LED device having dual molds according to the present invention;

FIG. 9 is a flowchart illustrating a method of manufacturing a white LED device having dual molds according to a first embodiment of the present invention;

FIG. 10 is a view illustrating a surface (a) of a conventional white LED device and a surface (b) of a white LED device having dual molds according to the present invention; and

FIG. 11 is a flowchart illustrating a method of manufacturing a white LED device having dual molds according to a second embodiment of the present invention.

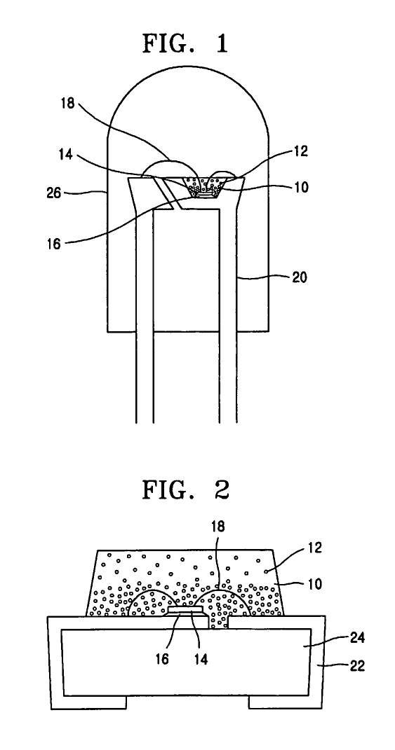

### DETAILED DESCRIPTION OF THE INVENTION

### Technical Goal of the Invention

The present invention provides a white LED device in which phosphor is uniformly dispersed in epoxy resin, the white LED device being relatively easy to manufacture and emitting a high-luminance pure white light that is close to natural white light and has excellent color temperature, etc.

Also, the present invention provides a method of manufacturing a white LED device in which phosphor is uniformly dispersed in epoxy resin, the white LED device emitting a high-luminance pure white light that is close to natural white light and has excellent color temperature, etc.

### Disclosure of the Invention

According to an aspect of the present invention, there is provided a white light emitting diode (LED) device having dual molds, the device including: an LED chip mounting member for mounting an LED chip; at least one blue or ultraviolet LED chip mounted on the LED chip mounting member; a first mold having a transparent epoxy resin and a first phosphor and sealing the blue or ultraviolet LED chip, the first phosphor dispersed in the transparent epoxy resin to convert light emitted from the blue or ultraviolet LED chip into first light having a first wavelength; and a second mold having a transparent epoxy resin and a second phosphor and formed on the first mold, the second phosphor dispersed in the transparent epoxy resin to convert light emitted from the blue or ultraviolet LED chip into second light having a second wavelength, the second light being white light obtained by combination of the emitted light and the first light.

The white LED device may further include a bonding wire for electrically connecting the blue or ultraviolet LED chip with an external connection terminal.

According to another aspect of the present invention, there is provided a method of manufacturing a white LED device having dual molds, the method including: mounting at least one blue LED chip or ultraviolet LED chip on an LED chip mounting member; forming a first mold having a transparent epoxy resin and a first phosphor to seal the blue or ultraviolet LED chip, the first phosphor dispersed in the transparent epoxy resin to convert light emitted from the blue or ultraviolet LED chip into first light having a first wavelength; and forming a second mold having a transparent epoxy resin and a second phosphor on the first mold, the second phosphor dispersed in the transparent epoxy resin to convert light emitted from the blue or ultraviolet LED chip into second light having a second wavelength, the second light being white light obtained by combination of the emitted light and the first light.

In the method of manufacturing the white LED device according to one embodiment of the present invention, the forming of the first mold and the forming of the second mold include: first mixing a main gradient with a curing agent at room temperature to provide a liquid-phase epoxy resin; first semi-curing the liquid-phase epoxy resin at a temperature of 70° C. to 100° C. and a pressure of 1 torr to 30 torr; adding and second mixing the first phosphor with the semi-cured liquid-phase epoxy resin at room temperature to prepare a first base resin having the mixed first phosphor; adding and second mixing the second phosphor with the semi-cured liquid-phase epoxy resin at room temperature to prepare a second base resin having the mixed second phosphor; molding and surrounding the mounted blue or ultraviolet LED chip with the first base resin; second curing the first base resin at a temperature of more than 120° C. and atmospheric pressure to form the first mold; molding the first mold with the second base resin; and second curing the second base resin at the temperature of more than 120° C. and atmospheric pressure to form the second mold.

In a manufacturing method according to another embodiment of the present invention, the forming of the first mold and the forming of the second mold can be performed by a transfer-molding technique using, respectively, a transparent epoxy resin tablet mixed with the first phosphor and a transparent epoxy resin tablet mixed with the second phosphor.

### EFFECT OF THE INVENTION

The inventive white LED device creates white light by mixing blue, red, and green light. Therefore, the white LED device has improved color rendering and spectral distribution to provide a good color temperature and emit white light close to natural white light. Moreover, the inventive white LED device has excellent color reappearance as well as high luminance and efficiency.

Meanwhile, the inventive white LED device manufacturing method has an advantage in that conventional manufacturing methods are all applicable. That is, the white LED device can be manufactured using a transfer-molding technique or the like, as well as a potting technique, and a screen pattern metal mask technique. Specifically, if a two-step curing process is used, the phosphor can be uniformly dispersed in the transparent epoxy resin. Therefore, the white LED device can be manufactured to have high luminance and excellent reproducibility.

The inventive white LED device having the dual mold has numerous applications such as in a display emitting white light, in automobile control displays, home appliances, electronic devices such as portable phones, in liquid crystal displays, etc. The inventive white LED device is applicable to electronic devices currently employing LEDs or fluorescent lamps.

### BEST MODE FOR CARRYING OUT THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. When the same element appears in more than one drawing, it is denoted by the same reference numeral in each drawing in which it appears.

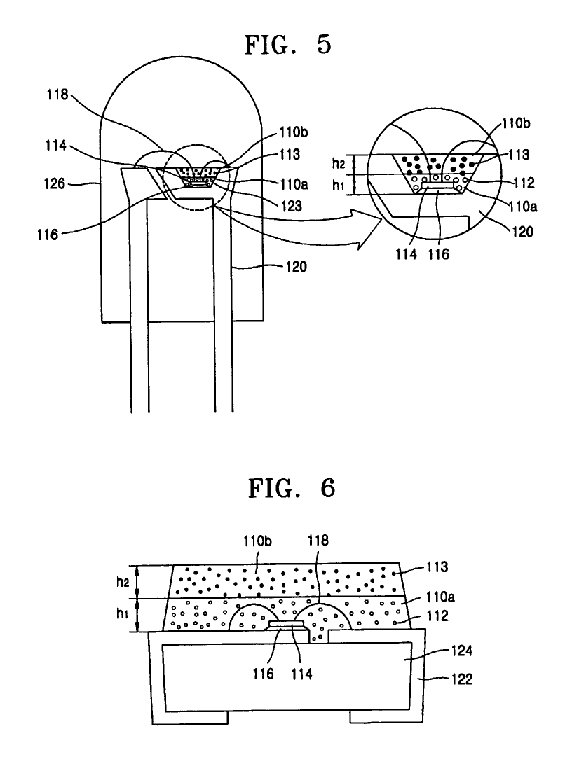

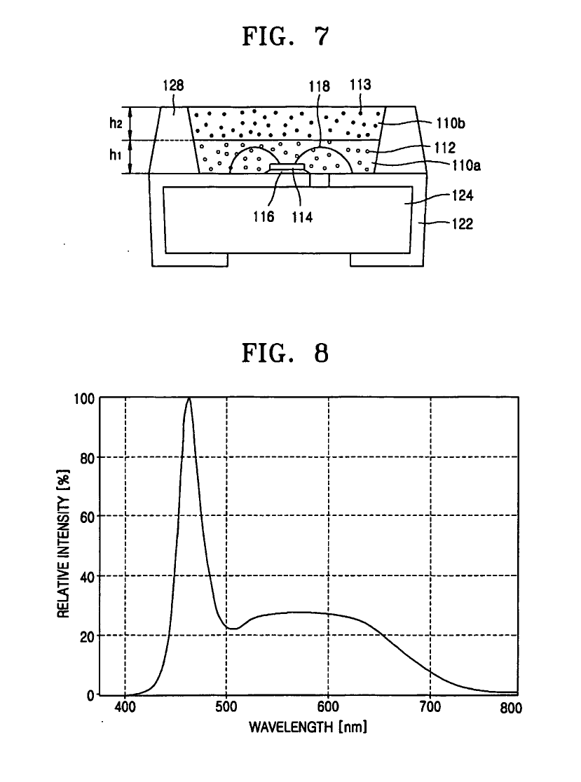

FIGS. 5 through 7 are schematic sectional views of white LED devices according to the present invention. Here, FIG. 5 illustrates a lamp-type white LED device, FIG. 6 illustrates a chip-type white LED device manufactured using a transfer-molding technique, and FIG. 7 illustrates a lead frame-type white LED device manufactured using an injection-molded housing package.

Referring to FIGS. 5 through 7, the white LED device includes an LED chip mounting member 120 or 124; at least one blue or ultraviolet LED chip 114; a first mold 110a and 112; and a second mold 110b and 113.

The lamp-type white LED device uses an electrode 120 as the LED chip mounting member, and other types of white LED devices use a board or a lead frame 124 as the LED chip mounting member. A necessary wire or lead 122 is provided at the board or the lead frame 124. The LED chip mounting members 120 and 124 of the present invention are the same as those of conventional art. Additionally, the present invention can also use an LED chip mounting member for mounting an LED chip in a flip-chip manner.

The LED chip 114 is mounted on the LED chip mounting members 120 and 124. The blue or ultraviolet LED chip 114 is used to manufacture the white LED device. As shown, the LED chip 114 can be adhered by an adhesive 116 with its bonding pad (not shown) directed upward or downward in the flip-chip manner. Additionally, one LED chip 114 can be mounted as shown, or two or more LED chips can be mounted.

The LED chip 114 is sealed by dual molds having a first mold 110a and 112 and a second mold 110b and 113. The first mold 110a and 112 is comprised of a transparent epoxy resin 110a and a first phosphor 112 uniformly dispersed in the transparent epoxy resin 110a to convert light emitted from the LED chip 114 into a first light having a first wavelength.

If the LED chip 114 is the blue LED chip, a compound (hereinafter referred to as “red phosphor”) is used as the first phosphor 112 to convert blue light into red light. The converted red light has a wavelength of about 620 nm to 670 nm. Meanwhile, if the LED chip 114 is the ultraviolet LED chip, a compound is used to convert ultraviolet light into light having a wavelength in the visible light region. The mixture of the first phosphor 112 and the transparent epoxy resin 110a is about 1% to 20% the first phosphor 112 by weight. The first phosphor 112 may have a particle diameter of about 25 μm. Not only are such small-sized particles advantageous in obtaining uniform dispersion, but if the phosphor particles have a larger diameter than the bonding wire 118, they can damage the bonding wire 118 during manufacture or in use.

A general epoxy resin compound is used as the transparent epoxy resin 110a without specific limitation. The transparent epoxy resin 110a should be at least as thick as the height of the LED 114. For example, the thickness (h₁) of the transparent epoxy resin 110a, that is, the first mold, can be about 10% to 90% of the combined thickness (h₁+h₂) of the first mold and the second mold.

The second mold 110b and 113 is formed on the first mold 110a and 112. Additionally, the second mold 110b and 113 is comprised of a transparent epoxy resin 110b; and a second phosphor 113 uniformly dispersed in the transparent epoxy resin 110b to convert light emitted from the LED chip 114 into second light having a second wavelength. Here, the second light is white light obtained by synthesis of the emitted light and the first light.

If the LED chip 114 is the blue LED chip, a compound (hereinafter referred to as “green phosphor”) for converting blue light into green light is used as the second phosphor 113. The converted green light has a wavelength of about 510 nm to 550 nm. Meanwhile, if the LED chip 114 is the ultraviolet LED chip, a compound for converting the first light into its complementary-colored light is used as the second phosphor 113. The second phosphor 113 can be about 1% to 20% by weight of the mixture of the second phosphor 113 and the transparent epoxy resin 110b. The second phosphor 113 may have a particle diameter of less than 25 μm. The general epoxy resin compound is used as the transparent epoxy resin 110b. Also, the thickness (h₂) of the transparent epoxy resin 110b, that is, the second mold, can be about 10% to 90% of the combined thickness (h₁+h₂) of the first mold and the second mold.

The inventive white LED device can further include a bonding wire 118. The bonding wire 118 is used to electrically connect the LED chip 114 with an external connection terminal (for example, the electrode 120, the printed circuit board circuit 124, or a lead 122 of the lead frame of FIG. 5). However, if a flip-chip package is used, the bonding wire 118 may not be required. Additionally, if the white LED device is a lamp-type, it further includes a mold cup 126. If the white LED device is a lead frame-type, it further includes the lead 122.

FIG. 8 is a graph of relative intensity versus wavelength of light emitted from the white LED device with the dual molds, using the blue LED chip, manufactured according to the present invention.

Referring to FIG. 8, in the inventive white LED device, the emitted light has a narrow peak in the blue wavelength region, but at longer visible wavelengths, there are no peaks in any specific wavelength regions and the entire spectrum has nearly uniform intensity. Accordingly, the emitted light of the inventive white LED device is more similar to natural light. For example, a conventional white LED device has a color temperature of about 5,000K due to its relatively weak red light. This is very different from sunlight which has a color temperature of about 6,000K to 6,500K. In contrast, the inventive white LED device has a color temperature of about 6,200K, which is much more similar to sunlight, i.e., natural light.

The conventional white LED device mixes blue light with its complementary yellow light to emit white light, but the inventive white LED device mixes light of all wavelength regions, for example, blue light, red light, and green light—the three primary colors—to emit white light. Accordingly, the inventive white LED device is advantageous in that since process conditions are relatively less complicated, productivity is high due to a small defect rate. In addition, the inventive white LED device has the advantage of less color temperature variation and better reliability than the conventional white LED device when used for an extended period of time generating a lot of heat.

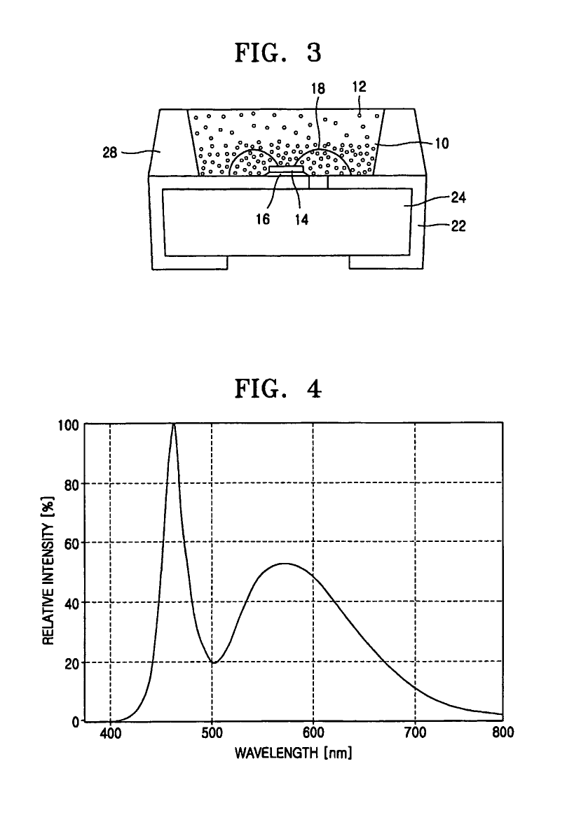

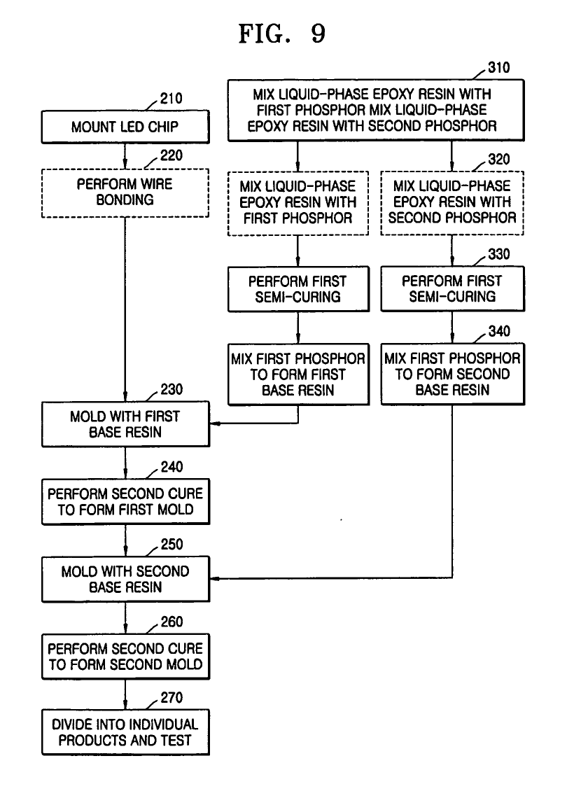

FIG. 9 is a flowchart illustrating a method of manufacturing the white LED device having the dual molds according to a first embodiment of the present invention. The white LED devices shown in FIGS. 5 through 7 are manufactured using the manufacturing method of FIG. 9. The white LED device of FIG. 3B can be manufactured by an adequate molding die using a transfer-molding technique, an inventive potting technique, or the like.

The inventive method of manufacturing the white LED device having the dual molds is characterized by a two-step curing process. In the two-step curing process, a first curing process is performed at a low pressure to semi-cure a liquid-phase epoxy resin so that the phosphor having a relatively large specific gravity can be uniformly dispersed in the transparent epoxy resin. After that, the phosphor is additionally mixed to perform a second curing process. This two-step curing process is described in detail in Korean Patent Application No. 1020030084173, filed on Nov. 25, 2003 by the present applicant, and incorporated herein in its entirety by reference. The method of manufacturing the white LED device with the dual molds using the two-step curing process will now be described.

Referring to FIG. 9, at least one LED chip 114 is firstly mounted on the LED chip mounting member 120 or 124 (S210). The LED chip 114 can be the blue LED chip or the ultraviolet LED chip. The LED chip 114 can be adhered to the LED chip mounting member 120 or 124 by the adhesive 116. Next, a wire bonding process is performed to electrically connect the LED chip 114 with the external connection terminal (S220). If the LED chip is mounted in the flip-chip way, the wire bonding process can be omitted.

Meanwhile, the two-step curing process is used to form the first mold 110a and 112 and the second mold 110b and 113. For this, a main gradient and a curing agent are first mixed with each other to manufacture the liquid-phase epoxy resin (S310). One of a cresol novolac epoxy, a phenol novolac epoxy, and a bisphenol A-type epoxy, or a combination thereof, can be used as the main gradient. Also, one of nonhydroxide, an aromatic amine denaturant, and a phenol novolac epoxy, or a combination thereof, can be used as the curing agent. Further, if necessary, a curing accelerator such as an imidazole compound or an amine compound can be added to promote a curing reaction.

The phosphor can be further added to perform the first mixing process (S320). If the blue LED chip is mounted, the red phosphor or the green phosphor is used. If the ultraviolet LED chip is mounted, two kinds of phosphors having a complementary-color relationship are used. However, a powder of silicon resin or epoxy mold compound (EMC) is not further added in the first mixing process.

After that, the first curing process is performed to semi-cure the compound (S330). The first curing process is performed at a pressure much lower than atmospheric pressure, at a predetermined temperature, and for a predetermined time. For example, the first curing process is performed at a pressure of about 1 torr to 30 torr, at a temperature of about 70° C. to 100° C., and for about one to two hours.

Next, the second mixing process is performed for the semi-cured epoxy resin to manufacture a first base resin and a second base resin (S340). Through the second mixing process, components of the semi-cured epoxy resin are better mixed. If the phosphor is added in the first mixing process, remaining phosphor is further added, and if the phosphor is not added in the first mixing process, necessary phosphor is added. Then, the second mixing process is performed. The amount of phosphor can be about 1% to 20% of the phosphor and semi-cured epoxy resin mixture, by weight. In the embodiment of the present invention where the blue LED chip is mounted, the red phosphor is used as the first phosphor, and the green phosphor is used as the second phosphor. As a result, the first base resin and the second base resin are prepared.

Still referring to FIG. 9, the prepared first base resin is used to firstly mold the LED chip 114 (S230). The first molding process can be performed using a conventional molding process such as a potting technique or a screen pattern mask technique. The first molding process may be performed to form the mold to a thickness of about 10% to 90% of the total mold thickness, and the thickness of the mold should be greater than the height of the mounted LED chip 114.

After the blue LED chip 114 is molded using the semi-cured first base resin, the second curing process is performed (S240). In the second curing process, the semi-cured base resin is completely cured. Unlike the first curing process, the second curing process can be performed even at atmospheric pressure, at a temperature higher than in the first curing process, for example, 120° C. to 130° C., for about 1 to 2 hours. As a result, the first base resin is completely cured to form the first mold 110a and 112.

The prepared second base resin is used to second mold the blue LED chip 114 which has been molded using the first mold 110a and 112 (S250). Like the first molding process, the second molding process can be performed using a conventional molding process such as the potting technique or the screen pattern mask technique. When the second molding process is completed, the white LED devices of FIGS. 5 to 7 are completed.

After the blue LED chip 114 is molded using the semi-cured second base resin, the second curing process is performed (S260). In the second curing process, the semi-cured base resin is completely cured. Unlike the first curing process, the second curing process can be performed even at atmospheric pressure, at a temperature higher than in the first curing process, for example, at 120° C. to 130° C., for about 1 to 2 hours. As a result, the first base resin is completely cured to form the second mold 110b and 113.

After a necessary subsequent process such as a cutting process is performed to separate individual products, like in the conventional art, a test is performed (S270).

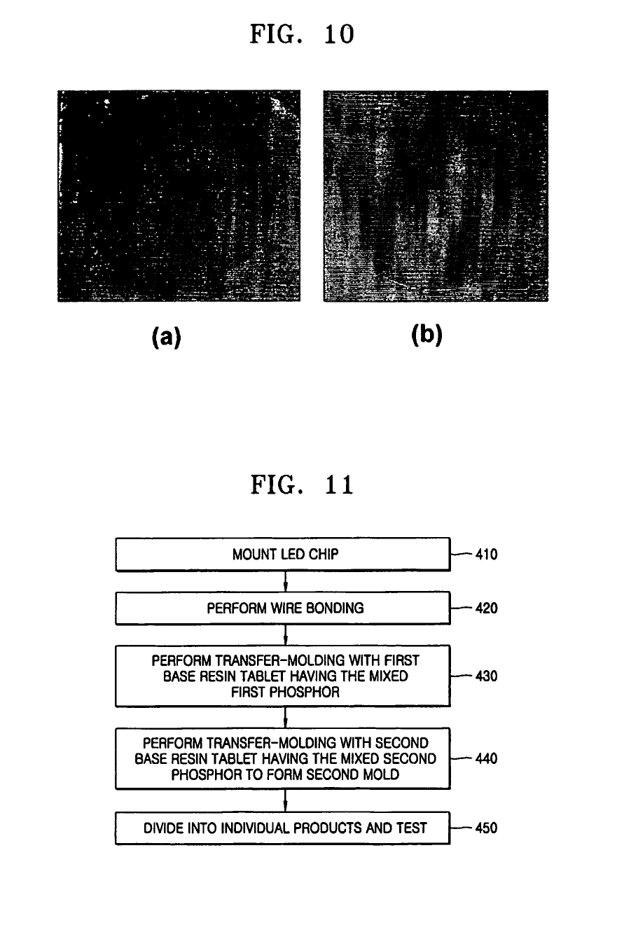

As in the first embodiment of the present invention, if the second curing process is performed, the semi-cured epoxy resin can cause a rapid, high-temperature curing reaction to prevent the phosphor with the relatively large specific gravity from sinking downward. FIG. 10 is a view illustrating a conventional white LED device (a) and a white LED device (b) manufactured using the two-step curing process. Referring to FIG. 10, in the conventional white LED device (a), the shape of the LED chip is clearly visible, but in the inventive white LED device (b), the shape of the LED chip is not clearly visible. This is because in the conventional white LED device (a), the phosphor is not uniformly dispersed and sinks down to the bottom of the mold, whereas in the inventive white LED device (b), the phosphor is uniformly dispersed. Accordingly, in the present invention, the white LED device can be manufactured to have less color dispersion in distribution and excellent reproducibility since the red phosphor and the green phosphor are uniformly distributed throughout the epoxy resin.

### EMBODIMENTS

FIG. 11 is a flowchart illustrating a method of manufacturing a white LED device having dual molds according to a second embodiment of the present invention.

The white LED device of FIG. 6 is manufactured using the manufacturing process of FIG. 11, which is characterized by use of a transfer-molding technique. The transfer-molding technique will be described only briefly because it is widely known in the field of LED chip packaging.

Referring to FIG. 11, after a chip adhering process is performed to mount the blue LED chip 114 on the LED chip mounting member 124 as in the first embodiment (S410), the wire bonding process (S118) is performed if needed (S420). Also, the transfer-molding technique is used to form the first mold 110a and 112 (S430). The transfer-molding technique can be performed using a first base resin tablet having the first phosphor, for example, the red phosphor 112, mixed in the epoxy mold compound (EMC). The first mold 110a and 112 is formed to have a predetermined thickness, for example, a thickness (h₁) that is 10% to 90% of the total mold thickness. Also, the transfer-molding technique is used to form the second mold 110b and 113 (S440). The transfer-molding technique can be performed using a second base resin tablet having the second phosphor, for example, the green phosphor 113, mixed in the epoxy mold compound. The second mold 110b and 113 is formed to have a predetermined thickness (h₂). The first base resin tablet and the second base resin tablet can be manufactured using a conventional known technology or an invention disclosed in Korean Patent Application No. 1020030051836, entitled “METHOD OF MANUFACTURING EPOXY RESIN COMPOUND FOR MOLDING OPTIC SEMICONDUCTOR DEVICE”, co-filed by the present applicant and incorporated herein in its entirety by reference. Finally, individual product cutting and any necessary tests are performed to complete the LED device (S450).

As described above, according to the second embodiment of the present invention, the high-performance white LED device with the dual molds can be manufactured by simply applying a conventional transfer-molding technique.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A white light emitting diode (LED) device comprising:
an LED chip mounting member for mounting an LED chip;
one or more than blue LED chips or ultraviolet LED chips mounted on the LED chip mounting member;
a first mold having a transparent epoxy resin and a first phosphor and sealing the blue or ultraviolet LED chips, the first phosphor dispersed in the transparent epoxy resin to convert light emitted from the blue or ultraviolet LED chips into first light having a first wavelength; and
a second mold having a transparent epoxy resin and a second phosphor and formed on the first mold, the second phosphor dispersed in the transparent epoxy resin to convert light emitted from the blue or ultraviolet LED chips into second light having a second wavelength, the second light being white light obtained by combination of the emitted light and the first light.

2. The device of claim 1, wherein the device has the blue LED chip, the first phosphor converts the emitted light into red light, and the second phosphor converts the emitted light into green light.

3. The device of claim 2, wherein each of the first phosphor and the second phosphor account for 1% to 20% of the weight of their respective mixtures with the transparent epoxy resin.

4. The device of claim 2, wherein a thickness of the first mold is 10% to 90% of a combined thickness of the first mold and the second mold.

5. The device of claim 1, further comprising a bonding wire for electrically connecting the blue or ultraviolet LED chips with an external connection terminal.

6. A method of manufacturing a white LED device, the method comprising:
mounting one or more than blue LED chips or ultraviolet LED chips on an LED chip mounting member;
forming a first mold having a transparent epoxy resin and a first phosphor to seal the blue LED chips or the ultraviolet LED chips, the first phosphor dispersed in the transparent epoxy resin to convert light emitted from the blue or ultraviolet LED chips into first light having a first wavelength; and
forming a second mold having a transparent epoxy resin and a second phosphor on the first mold, the second phosphor dispersed in the transparent epoxy resin to convert light emitted from the blue or ultraviolet LED chips into second light having a second wavelength, the second light being white light obtained by combination of the emitted light and the first light.

7. The method of claim 6, wherein the forming of the first mold and the forming of the second mold each comprise:
first mixing a main gradient with a curing agent at room temperature to provide a liquid-phase epoxy resin;
first semi-curing the liquid-phase epoxy resin at a temperature of 70° C. to 100° C. and a pressure of 1 torr to 30 torr;
adding and second mixing the first phosphor with the semi-cured liquid-phase epoxy resin at room temperature to prepare a first base resin having the mixed first phosphor;
adding and second mixing the second phosphor with the semi-cured liquid-phase epoxy resin at room temperature to prepare a second base resin having the mixed second phosphor;
molding and surrounding the mounted blue or ultraviolet LED chip with the first base resin;
second curing the first base resin at a temperature of more than 120° C. and atmospheric pressure to form the first mold;
molding the first mold with the second base resin; and
second curing the second base resin at the temperature of more than 120° C. and atmospheric pressure to form the second mold.

8. The method of claim 7, wherein the preparing of the base resin is performed using a potting technique or a screen pattern mask technique.

9. The method of claim 7, wherein in the first mixing, the first phosphor or the second phosphor is further added and mixed, and the first base resin is formed using the liquid-phase epoxy resin mixed with the first phosphor and semi-cured, and the second base resin is formed using the liquid-phase epoxy resin mixed with the second phosphor and semi-cured.

10. The method of claim 6, wherein the forming of the first mold and the forming of the second mold are performed by a transfer-molding technique using, respectively, a transparent epoxy resin tablet mixed with the first phosphor and a transparent epoxy resin tablet mixed with the second phosphor.

11. The method of claim 6, wherein the white LED device has the blue LED chips, the first phosphor converts the emitted light into red light, and the second phosphor converts the emitted light into green light.

12. The method of claim 11, wherein each of the first phosphor and the second phosphor account for 1% to 20% of the weight of their respective mixtures with the transparent epoxy resin.

13. The method of claim 6, wherein the thickness of the first mold is 10% to 90% of the combined thickness of the first mold and the second mold.

14. The method of claim 6, after the adhering of the chip, further comprising:
bonding a wire to electrically connect the blue or ultraviolet LED chips with an external connection terminal.
